(19) United States
(12) Patent Application Publication
(10) Pub. No.: US 2026/0056742 A1
(43) Pub. Date: Feb. 26, 2026

(54) PROCESSING UNIT OF MEMORY FOR TABLE LOOKUP

(71) Applicant: Micron Technology, Inc., Boise, ID (US)

(72) Inventors: Timothy P. Finkbeiner, Boise, ID (US); Glen E. Hush, Boise, ID (US); Peter L. Brown, Eagle, ID (US); Xinyu Wu, Boise, ID (US)

(21) Appl. No.: 19/274,904

(22) Filed: Jul. 21, 2025

Related U.S. Application Data
(60) Provisional application No. 63/686,451, filed on Aug. 23, 2024.

(51) Int. Cl. G06F 9/30

(52) U.S. Cl. CPC G06F 9/30047; G06F 9/30032; G06F 9/30036; G06F 9/30134

(57) ABSTRACT

A processing unit of memory for table lookup is described herein. A plurality of elements (e.g., output values) of a lookup table (LUT) can be sequentially prefetched from a respective column of memory cells that is indicated by each vector value of vector values stored in positions of a register of the processing unit. Each of the vector values can be shifted by one position among the positions of the register to cause a terminal position of the register to be available for storing the respective output value among the prefetched output values.

### PRIORITY INFORMATION

This application claims the benefit of U.S. Provisional Application No. 63/686,451, filed Aug. 23, 2024, the contents of which are incorporated herein by reference.

### TECHNICAL FIELD

The present disclosure relates generally to memory, and more particularly to a processing unit of memory for table lookup.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory is also utilized as volatile and non-volatile data storage for a wide range of electronic applications. Non-volatile memory may be used in, for example, personal computers, portable memory sticks, digital cameras, cellular telephones, portable music players such as MP3 players, movie players, and other electronic devices. Memory cells can be arranged into arrays, with the arrays being used in memory devices.

### BRIEF DESCRIPTION OF THE DRAWINGS

FIG. 1 is a block diagram of an apparatus in the form of a computing system including a memory device in accordance with a number of embodiments of the present disclosure.

FIG. 2 is a block diagram of a processing unit for a table lookup in accordance with a number of embodiments of the present disclosure.

FIG. 3 illustrates an example of shifting data values in vector registers in association with performing a table lookup operation in accordance with a number of embodiments of the present disclosure.

FIG. 4 illustrates an example flow diagram of a method for performing a table lookup operation using a processing unit of memory in accordance with a number of embodiments of the present disclosure.

FIG. 5 illustrates an example machine of a computer system within which a set of instructions, for causing the machine to perform any one or more of the methodologies discussed herein, can be executed.

### DETAILED DESCRIPTION

The present disclosure includes a processing unit for a table lookup. An example method can include prefetching data values corresponding to a plurality of elements from a column of memory cells. The column can be indicated by a first vector value of a plurality of vector values stored in a plurality of positions of a register. The method can further include shifting, by one position and toward a first position of the plurality of positions, each of the plurality of vector values stored in the register to cause a second position of the plurality of positions to be unoccupied. The method can further include storing, in the second position of the register, one of the plurality of elements indicated by the first vector value.

A perceptron is the fundamental computing element used to implement a wide range of artificial intelligence (AI) and machine learning algorithms. As used herein, artificial intelligence (AI) refers to the ability to improve an apparatus through “learning” such as by storing patterns and/or examples which can be utilized to take actions at a later time. Machine learning, which can be a subset of AI, refers to algorithms that can learn from and make predictions or decisions based on data.

A perceptron consists of a weight vector and an input vector. The perceptron computes the inner product of these vectors and then applies a non-linear function, known as an activation function, to the resulting sum. Activation functions can range from simple clipping functions to more complex functions, such as exponentials or polynomial expansions. These more complex functions can often be costly to implement, as they require a larger die area for the hardware circuitry and can significantly impact the overall performance by increasing the computational load and power consumption. However, activation functions can be simplified by describing them using a lookup table (LUT). As used herein, the term “lookup table” or “LUT” refers to a data structure that maps input values to corresponding (e.g., precomputed) output values. The LUT is designed for fast retrieval and is often used to optimize performance by replacing runtime computations with precomputed results, thereby minimizing hardware complexity and improving performance.

Embodiments of the present disclosure describe hardware circuitry that can be implemented as part of AI accelerator architecture to provide fast retrieval of output values from a LUT. This hardware circuitry features a relatively simple design compared to those used for performing table lookup operations in previous approaches. The hardware circuitry can be implemented for each unit of an array of memory cells, such as a bank of memory cells. Accordingly, this hardware implementation can be replicated across each of the banks in the accelerator. The architecture allows for parallel execution of the lookup function, which not only increases the system's efficiency but also significantly enhances its overall performance by reducing latency and improving throughput.

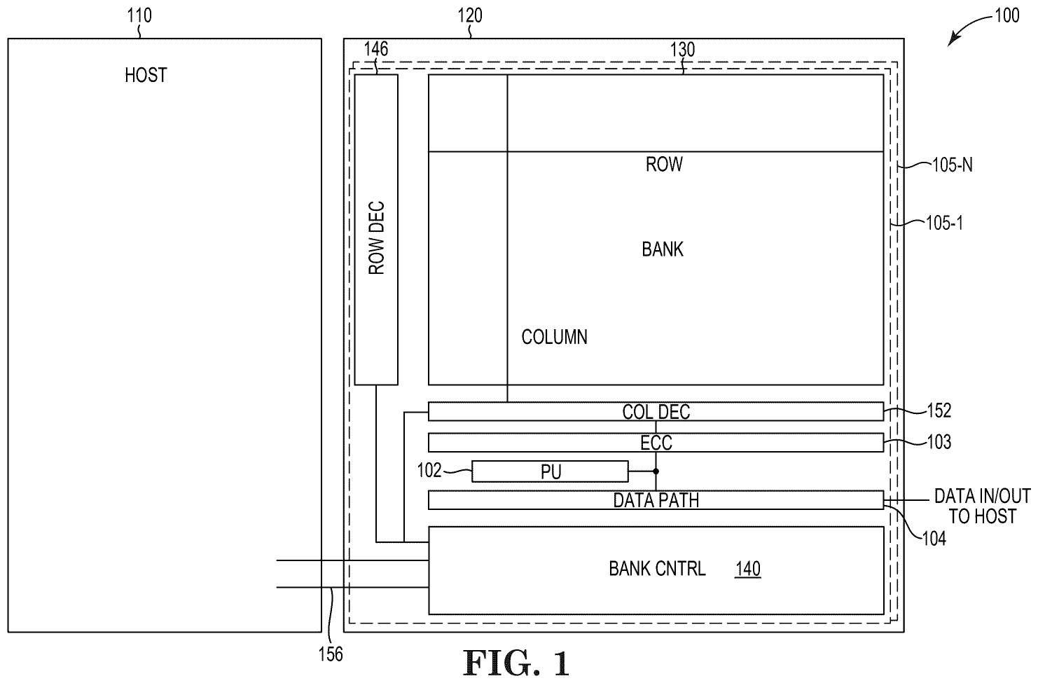

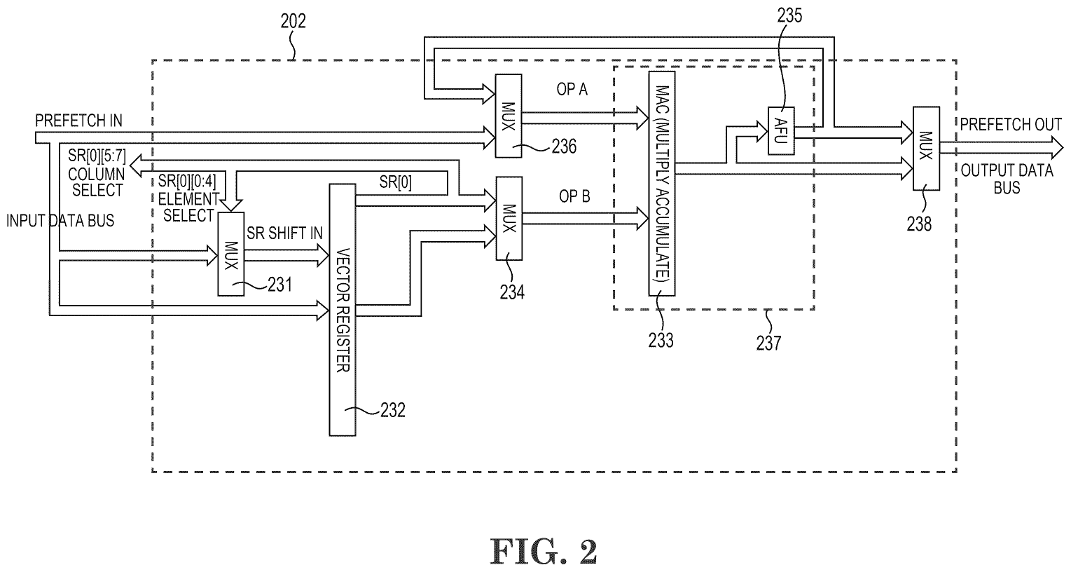

The figures herein follow a numbering convention in which the first digit or digits correspond to the drawing figure number and the remaining digits identify an element or component in the drawing. Similar elements or components between different figures may be identified by the use of similar digits. For example, 102 may reference element “02” in FIG. 1, and a similar element may be referenced as 202 in FIG. 2. Analogous elements within a Figure may be referenced with a hyphen and extra numeral or letter. Such analogous elements may be generally referenced without the hyphen and extra numeral or letter. For example, elements 105-1, 105-2, . . . , 105-N in FIG. 1 may be collectively referenced as 105. As used herein, the designator “N”, particularly with respect to reference numerals in the drawings, indicates that a number of the particular feature so designated can be included. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram of an apparatus in the form of a computing system 100 including a memory device 120 in accordance with a number of embodiments of the present disclosure. As used herein, a memory device 120, a number of banks 130 of memory cells (also referred to as a memory array 130), a host 110, and/or the PU might also be separately considered an “apparatus.”

In this example, system 100 includes a host 110 coupled to memory device 120 via an interface 156. The computing system 100 can be a personal laptop computer, a desktop computer, a digital camera, a mobile telephone, a memory card reader, or an Internet-of-Things (IoT) enabled device, among various other types of systems. Host 110 can include a number of processing resources (e.g., one or more processors, microprocessors, or some other type of controlling circuitry) capable of accessing memory 120. The system 100 can include separate integrated circuits, or both the host 110 and the memory device 120 can be on the same integrated circuit. For example, the host 110 may be a system controller of a memory system comprising multiple memory devices 120, with the system controller 110 providing access to the respective memory devices 120 by another processing resource such as a central processing unit (CPU).

In the example shown in FIG. 1, the host 110 is responsible for executing an operating system (OS) and/or various applications that can be loaded thereto (e.g., from memory device 120 via controller 140). The host 110 can provide access commands and/or security mode initialization commands to a memory device via the interface 156.

For clarity, the system 100 has been simplified to focus on features with particular relevance to the present disclosure. The memory array 130 can be a DRAM array, SRAM array, STT RAM array, PCRAM array, TRAM array, RRAM array, NAND flash array, and/or NOR flash array, for instance. The arrays 130 can comprise memory cells arranged in rows coupled by access lines (which may be referred to herein as word lines or select lines) and columns coupled by sense lines (which may be referred to herein as digit lines or data lines).

The memory device 120 includes address circuitry to latch address signals provided over the interface 156. The interface 156 can include, for example, a physical interface employing a suitable protocol (e.g., a data bus, an address bus, and a command bus, or a combined data/address/command bus). Such protocol may be custom or proprietary, or the interface 156 may employ a standardized protocol, such as Peripheral Component Interconnect Express (PCIe), Gen-Z, CCIX, or the like. Address signals are received and decoded by a row decoder 146 and a column decoder 152 to access the memory array 130. Data can be read from memory arrays 130 by sensing voltage and/or current changes on the sense lines using sensing circuitry. The sensing circuitry can comprise, for example, sense amplifiers that can read and latch a page (e.g., row) of data from the memory array 130. The I/O circuitry can be used for bi-directional data communication with host 110 over the interface 156. Read/write circuitry is used to write data to the memory array 130 or read data from the memory array 130.

Controller 140 decodes signals provided by the host 110. These signals can include chip enable signals, write enable signals, and address latch signals that are used to control operations performed on the memory array 130, including data read, data write, and data erase operations. In various embodiments, the controller 140 is responsible for executing instructions from the host 110. The controller 140 can comprise a state machine, a sequencer, and/or some other type of control circuitry, which may be implemented in the form of hardware, firmware, or software, or any combination of the three.

In various instances, the controller 140 can receive signals provided by the host 110 including signals requesting operations to be performed by the PU 102. As used herein, the PU 102 can include hardware, firmware, and/or software for performing operations, such as, for example, multiplication operations and table lookup operations, using data provided by the memory array 130 and/or the host 110.

In various examples, error correction code (ECC) circuitry 103 can be coupled to the column decoder 152. The ECC circuitry 103 can receive data from the memory array 130. The ECC circuitry 103 can perform error correction operations to correct errors in data sensed from the memory array 130. The PU 102 can be coupled to the ECC circuitry 102. The PU 102 can perform a plurality of operations on data received from the ECC circuitry 103. The PU 102 can provide an output to the data path 104. The data path 104 can provide data to the interface 156. In various instances, the data path 104 can include Input/Output (I/O lines) and/or receivers and/or drivers. As used herein, receivers can include circuitry configured to receive a signal. Drivers can describe circuitry to drive a signal across a line or a plurality of lines. Although FIG. 1 illustrates a single decoder (e.g., row and column decoders 146, 156), ECC circuitry 103, and a PU 102, embodiments are not so limited. For example, the memory device 120 can include multiple layers, such as layers 105-1, . . . , 105-N(collectively referred to as layers 105) with each layer 105 including a bank 130, a decoder (e.g., row and column decoders 146, 156), ECC circuitry 103, and a PU 102. Alternatively speaking, the memory device 120 can include multiple banks, decoders, ECC circuitry, and PUs.

Each PU 102 can include one or more registers (e.g., register 232 illustrated in FIG. 2) and/or MUXes (e.g., MUXes 231 illustrated in FIG. 2) that can collaboratively be utilized for performing table lookup operations. The registers can be initially loaded with vector values that can function as input values for corresponding output values of an LUT (stored in one or more banks 130). One or more LUTs can be stored in the arrays 130. Using the vector values, the PU 102 can sequentially load the corresponding output values into the registers in a manner that the vector values stored in the registers are eventually replaced with the corresponding output values.

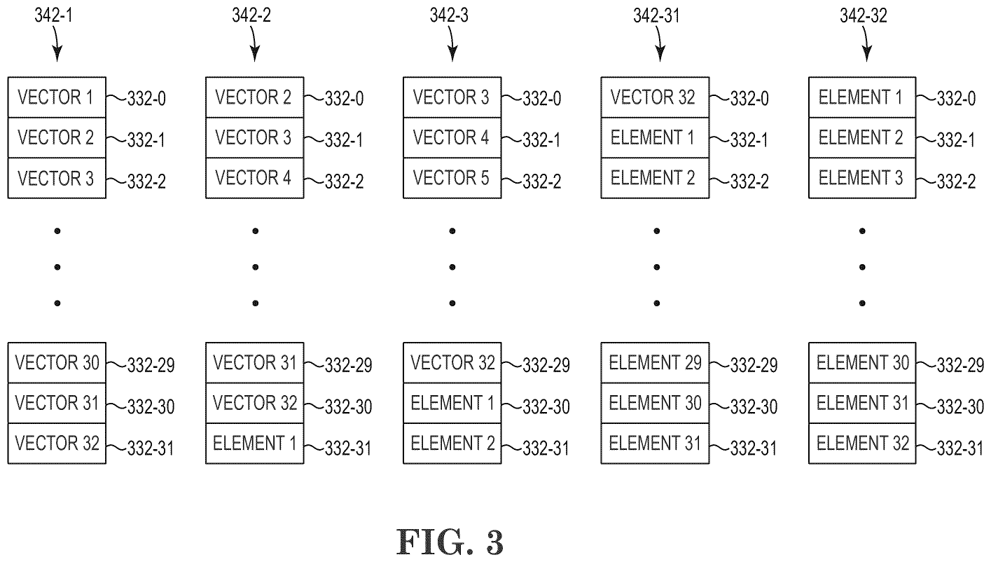

In some embodiments, multiple table lookup operations can be performed by the PUs 102 (e.g., using LUTs respectively stored in multiple banks 130) in parallel. For example, a table lookup operation can be performed by one PU 102 using data corresponding to an LUT stored in the bank 130 of the layer 105-1, while another table lookup operation is being performed by another PU 102 using data corresponding to an LUT stored in the bank 130 of the layer 105-N. Further details of the table lookup process are described in connection with FIGS. 2 and 3.

FIG. 2 is a block diagram of a processing unit 202 (e.g., PU 102 of FIG. 1) for a table lookup in accordance with a number of embodiments of the present disclosure. As illustrated and described in association with FIG. 1, the PU 202 can be located on a memory device-side (e.g., on the memory device 120 illustrated in FIG. 1); thereby, allowing the memory device 120 to perform the operations described herein using the PU 202.

The PU 202 can include multiplexors (MUXes) 231, 234, 236, 238, a shift register 232, a multiply-accumulate (MAC) unit 233, and arithmetic functional unit (AFU) 235. Although a single MAC unit 233 is shown, the PU 202 can include a plurality of MAC units. The PU 202 can receive data via an input data bus (e.g., including receivers and/or drivers), which can be 256-bit wide, although embodiments are not so limited. The input data bus can couple the PU 202 to one or more banks (e.g., bank 130 illustrated in FIG. 1) of the memory device (e.g., the memory device 120 illustrated in FIG. 1) and/or a host (e.g., the host 110 illustrated in FIG. 1) coupled to the memory device.

A table lookup operation can be initiated by loading (e.g., storing) the vector register 232 with vectors (alternatively referred to as “vector values”). The vectors can be received from a bank (e.g., DRAM array) of the memory device and/or the host coupled to the memory device. Although embodiments are not so limited, the vectors initially loaded to the vector register 232 can consist of thirty-two sets, each having 8 bits, amounting to a total of 256 bits. Thirty-two 8-bit vectors can be provided in a single 256-bit data chunk via the input data bus. The vectors can include values that will be “looked up.” The vectors can be an input to the table lookup operations. The vectors can be used to generate the output values as described below.

The register 232 can be representative of multiple registers. For example, the register 232 can be comprised of thirty-two 8-bit registers. Although embodiments are not so limited, the registers 232 can be shift registers, which can shift data values (e.g., vector values or output values of an LUT) stored in respective “positions” of the shift registers 232 toward a particular direction by one position. For example, thirty-two 8-bit registers provide thirty-two “positions”, in which thirty-two vectors can be respectively stored and the vectors can be shifted in each iteration by one position.

Subsequent to the registers 232 being loaded with vectors, a row of memory cells storing data corresponding to an LUT can be activated (e.g., by the row decoder 146 as controlled by the controller 140 shown in FIG. 1). For example, the data corresponding to the LUT can include a number of (e.g., precomputed) output values (alternatively referred to as “elements”, “lookup table elements”, or “LUT elements”) that can be mapped to input values. In the example illustrated in FIG. 2, the vectors loaded to the register 232 can function as “input values” of the LUT that can be respectively mapped (e.g., matched) to the output values of the LUT.

Each vector can be used to indicate, retrieve, and further load (e.g., store) one of the LUT elements into the vector registers 232. For example, each vector stored in the vector registers 232 can be utilized to select a particular column of memory cells which can correspond to a column of the LUT and a specific element within that column of memory cells. For example, a first portion of the bits (e.g., “SR[0][5:7]” shown in FIG. 2) in each vector can be used to select a specific column of the activated row. As a result, data (e.g., 32 elements) corresponding to the selected column can be prefetched onto a data bus (e.g., “input data bus” coupled to the PU 202) and provided (presented) to the MUX 231.

Once the elements are prefetched and presented on the data bus, the vector registers 232 can “discard” the vector used to prefetch elements corresponding to the selected column. For example, the vector registers 232, which can function as shift registers, can shift the position of the stored vectors towards to the first position (e.g., (e.g., the position 332-0 illustrated in FIG. 3 and alternatively referred to as “initial position”). This shifts a vector previously stored in the second position (e.g., the position 332-1 illustrated in FIG. 3) to the first position, while “emptying” the last position (e.g., the 32nd position and alternatively referred to as “terminal position), making it available for subsequent data.

A second portion of bits (e.g., “SR[0][0:4]” shown in FIG. 2) of each vector can function as “control signal” for the MUX 231. The second portion of bits can be used to select an element from the prefetched elements. For example, the second portion of bits provided to the MUX 231 can cause the MUX 231 to select and output one of the prefetched elements as indicated by the second portion of bits. The selected element output from the MUX 231 can be loaded (e.g., stored) into the “last position” of the shift registers 232 that became available as a result of the vector being discarded.

In a number of embodiments, the second portion of bits can be presented to the MUX 231 substantially simultaneously with the present of the first portion of bits to a respective row decoder (e.g., the row decoder 146) to prefetch the respective column. As used herein, the term “substantially” means that the characteristic need not be absolute, but is close enough so as to achieve the advantages of the characteristic. For example, “substantially simultaneously” is not limited to operations or events that are performed absolutely simultaneously and can include timings that are intended to be contemporaneous but due to manufacturing limitations may not be precisely simultaneously.

Alternatively, vectors stored in the registers 232 can be “rotated”, in which the vector previously stored in the first position (e.g., the position 332-0 illustrated in FIG. 3) can be shifted to the last position (e.g., the position 332-31 illustrated in FIG. 3). In this example, the last position storing the vector that was previously stored in the first position can be overwritten with the selected element output from the MUX 231.

Consider an example in which an LUT having 256 elements (each element having a size of 1 byte, thereby making the total size of the lookup table 256 bytes) is stored in at least a portion of a row of memory cells (e.g., a row of memory cells having a size of 2k bytes) and over 8 columns (with each column storing 32 elements) of the array (e.g., bank 130 illustrated in FIG. 1). The registers 232 are initially loaded with thirty-two vectors with each vector comprising 8 bits. In the first iteration, three bits (“SR[0][5:7]” shown in FIG. 2) of the first vector (“SR[0]” shown in FIG. 3) can be utilized (e.g., indicate) to prefetch elements of one of 8 columns (that are provided to the MUX 231, and 5 bits (“SR[0][0:4]” shown in FIG. 2) of the first vector (“SR[0]” shown in FIG. 3) can be utilized to indicate one of 32 elements of the selected column to cause the indicated element to eventually be loaded to the register 232.

Each iteration of discarding one vector and loading a respective element into the registers 232 can be repeated until every vector initially loaded into the vector registers 232 is exhausted (e.g., has been replaced by an element). For example, if the vector register 232 is initially loaded with 32 vectors, the iteration can be repeated thirty-two times to discard and exhaust the thirty-two vectors and fill the register 232 with thirty-two elements of the LUT, as a result. Further details of this iterative process are illustrated in association with FIG. 3.

The PU 202 further includes a logic unit 237. As shown in FIG. 2, the logic unit 237 includes a multiply-accumulate (MAC) unit 233 and an arithmetic functional unit 235. However, embodiments are not limited to particular types of units, circuits, etc. that can be included as part of the logic unit 237. In some embodiments, the PU 202 may not include logic units (e.g., the logic unit 237) such that an output from the vector register 232 can be sent out (e.g., via the MUX 234) without being processed at the logic units.

Each MAC unit 233 can include a multiplicator and an accumulator also referred to as accumulation registers). Each of the MAC units 233 can receive data values of operands “A” and “B” (respectively shown as “OP A” and “OP B” in FIG. 2) as respective inputs. For example, an operand “A” can be received from the MUX 236, which can selectively provide one of its inputs (e.g., received from the bank 130 of the memory device 120 or the AFU 235) to the MAC 233. Further, for example, an operand “B” can be received from the MUX 234, which can selectively provide one of its inputs (e.g., vectors, LUT elements, etc. received from the register 232) to the MAC 233.

The multiplicator and the accumulator of each respective MAC unit 233 can perform a plurality of multiplication operations and a plurality of accumulation operations (collectively referred to as MAC operations) utilizing the received data values from the operands “A” and “B”. The output of each respective multiplicator can be provided to a different respective accumulator. Each accumulator can sum the respective output of the multiplicators and the previous outputs of the multiplicators.

The AFU 235 can perform various arithmetic operations using inputs received from the MAC unit 233 as respective operands of the arithmetic operations. Although embodiments are not so limited, the AFU 235 can be a logic unit that performs non-linear mapping of input values to output values (e.g., Rectified Linear Unit, ReLU, (e.g., f(x)=|x|)). The mapping can be reconfigured at run time, as the lookup table is written to the memory array by the host. As an example, the AFU 235 performing the non-linear mapping can enable the handling of complex computational tasks (that goes beyond traditional linear arithmetic operations) such as those required in machine learning and signal processing

In some embodiments, the MAC unit 233 may be capable of handling a larger size of data (24-bit MAC unit) compared to the AFU 235 (e.g., 8-bit AFU). To achieve precision between the MAC unit 233 and the AFU 235, the MAC unit 233 can be implemented with a shift function, which allows the MAC unit 233 to selectively provide a portion of its 24-bit data (e.g., 8 bits) to the AFU 235.

The logic unit 237 can perform various operations, ranging from relatively complex operations to simple tasks, such as reading data values (e.g., vectors, LUT elements, etc.) stored in the register 232. For example, the logic unit 237 can be utilized to perform those activation functions associated with an artificial neural network (ANN), such as a threshold function, a sign function, a sigmoid function, or a linear function, although embodiments are not so limited.

In another example, reading data values from the register 232 can involve providing data values with a numerical value of “1” to the MAC unit 233 as operand “A” and an LUT element (or vector) to the MAC unit 233 as operand “B”. The multiplication performed by the MAC unit 233 using these two operands can result in an output equal to the input LUT element (as a result of a numerical value corresponding to the input LUT element multiplied by a numerical value “1”). The output (which corresponds to the input LUT element) from the MAC unit 233 can be transferred out (e.g., to the host) via the MUX 238. Outputs from the AFU 235 and MAC 233 can be provided to the MUX 238 as respective inputs, which can selectively transfer out one of its inputs via “output data bus” shown in FIG. 2 to the host (e.g., the host 110 shown in FIG. 1), for example.

FIG. 3 illustrates an example of shifting process of data values in vector registers in association with performing a table lookup operation in accordance with a number of embodiments of the present disclosure. Thirty-two positions (e.g., positions 332-0, . . . , 332-31) shown in FIG. 3 can be positions among which data values stored in the registers (e.g., the register 232 shown in FIG. 2) can be shifted toward a particular direction. More particularly, thirty-two positions 332-0, . . . , 332-31 can be representative of thirty-two registers (e.g., 8-bit registers). Although FIG. 3 illustrates thirty-two positions of shift registers (e.g., shift registers 232 illustrated in FIG. 2), embodiments are not limited to a particular quantity of positions among which data values stored in the shift registers can be shifted around.

At 342-1, the shift registers 232 are initially loaded with vectors (e.g., vectors “1” to “32” shown in FIG. 3) in positions 332-0, . . . , 332-31, respectively. As described in association with FIG. 2, bits of each vector are used to identify one of LUT elements to be mapped to the respective vector. At 342-2, assuming that the LUT element “1” is mapped to the vector “1”, the vectors “1” to “32” are shifted toward the position 332-0 by one position in a manner that the vector “1” is discarded from the shift register 232 and the last position 332-31 becomes “empty” to be eventually loaded with the element “1”. Similarly, at 342-3, assuming that the LUT element “2” is mapped to the vector “2”, the vectors “2” to “32” as well as LUT element “1” are shifted toward the position 332-0 by one position in a manner that the vector “2” is discarded from the shift register 232 and the last position 332-31 again becomes “empty” to be eventually loaded with the LUT element “2”.

The process of discarding one vector from and loading a respective LUT element (e.g., mapped to the discarded vector) to the shift registers 232 can be iteratively repeated for the number of times until all of the vectors “1” to “32” are exhausted (e.g., discarded). For example, to exhaust thirty-two vectors (e.g., vectors “1” to “32”), the process can be iteratively repeated thirty-two times. More particularly, at the 31st iteration (as shown at 342-31), the last position 332-31 is loaded with the LUT element “31” as a result of exhausting the vector “31” previously stored at the position 332-0, which is now loaded with the vector “32” at the end of the 31st iteration. Furthermore, at the 32nd iteration (as shown at 342-32), the last position 332-31 is loaded with the LUT element “32” as a result of exhausting the vector “32” previously stored at the position 332-0, which is now loaded with the LUT element “1” at the end of the 32nd iteration. As a result of thirty-two iterations, the thirty-two positions 332-0, . . . , 332-31 of the shift registers 232 are loaded with thirty-two LUT elements “1” to “32” as shown in FIG. 3.

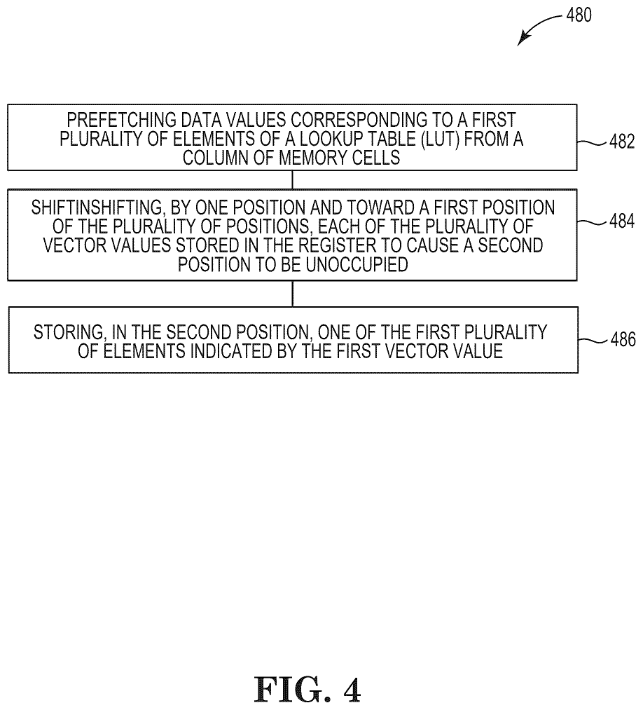

FIG. 4 is a flow diagram of an example method 480 for performing a table lookup operation using a processing unit of memory in accordance with some embodiments of the present disclosure. The method can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method is performed by or using the memory device 120 of computing system 100 shown in FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At 482, data values corresponding to a first plurality of elements can be prefetched from a first column of memory cells (e.g., responsive to receiving a command to perform a table lookup operation). The first column is indicated by a first vector value (e.g., “VECTOR 1” shown in FIG. 3) of a plurality of vector values (e.g., “VECTOR 1” to “VECTOR 32” shown in FIG. 3) stored in a plurality of positions (e.g., the positions 332-1, . . . , 332-32 illustrated in FIG. 3) of a register (e.g., register 232, 332 shown in FIGS. 2 and 3). For example, the first plurality of elements to be prefetched can be indicated by a first portion of bits (“SR[0][5:7]” shown in FIG. 2) of the respective data value.

The first plurality of elements can respectively correspond to output values of a lookup table (LUT). In some embodiments, a row of memory cells configured to store data corresponding to the LUT can be activated prior to prefetching the data values corresponding to the first plurality of elements from the first column of memory cells.

At 484, each of the plurality of vector values stored in the register 232, 332 can be shifted by one position and toward a first position (e.g., the position 332-1 illustrated in FIG. 3) of the plurality of positions to cause a second position (e.g., the position 332-31 illustrated in FIG. 3) of the plurality of positions to be unoccupied. At 486, one of the first plurality of elements (e.g., “ELEMENT 1” shown in FIG. 3) indicated by the first vector value can be stored in the second position 332-31 of the register 232, 332. For example, the one of the first plurality of elements to be stored in the register 232, 332 can be indicated by a second portion of bits (“SR[0][0:4]” shown in FIG. 2) of the first vector value.

Subsequent to storing the one of the first plurality of elements in the second position 332-31 of the register 232, 332, a second plurality of elements can be prefetched from a second column of memory cells. The second column can be the same column as the first column (in which the second plurality of elements are analogous to the first plurality of elements) or a different column than the first column (in which the second plurality of elements may be different form the first plurality of elements). This second column is indicated by a second vector value (“VECTOR 2” shown in FIG. 2) of the plurality of vector values that is stored in the first position 332-1 of the register 232, 332. In this example, each of the plurality of vector values stored in the register 232, 332 can be shifted by one position and toward the first position 332-1 to cause the second position 332-31 of the plurality of positions to be unoccupied. Further, one of the second plurality of elements (e.g., “ELEMENT 2” shown in FIG. 3) indicated by the second vector value can be stored in the second position 332-31 of the register 232, 332.

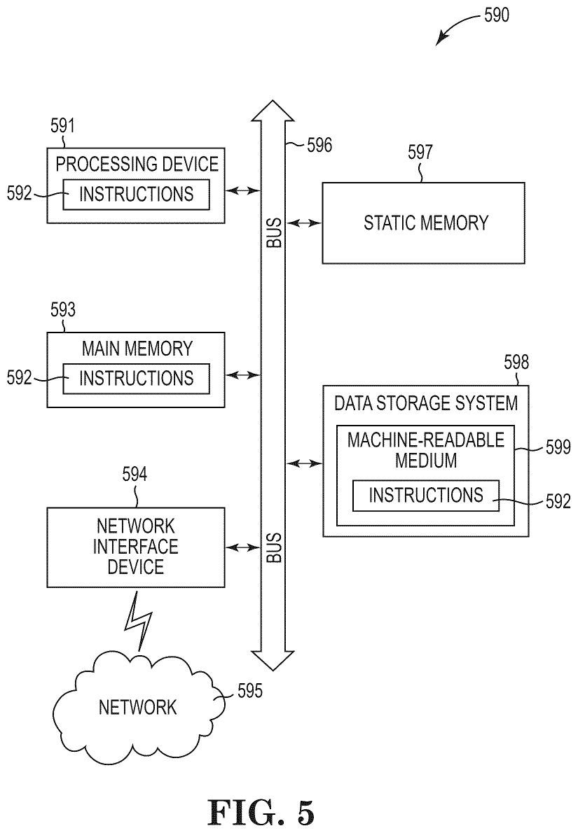

FIG. 5 illustrates an example machine of a computer system 590 within which a set of instructions, for causing the machine to perform any one or more of the methodologies discussed herein, can be executed. In some embodiments, the computer system 590 can correspond to a host system (e.g., the host 110 of FIG. 1) that includes, is coupled to, or utilizes a memory device (e.g., the memory device 120 of FIG. 1) or can be used to perform the operations of the PU (e.g., the PU 102 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 590 includes a processing device 591, a main memory 593 (e.g., read-only memory (ROM), flash memory, dynamic random access memory (DRAM) such as synchronous DRAM (SDRAM) or Rambus DRAM (RDRAM), etc.), a static memory 597 (e.g., flash memory, static random access memory (SRAM), etc.), and a data storage system 598, which communicate with each other via a bus 596.

Processing device 591 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 591 can also be one or more special-purpose processing devices such as an application specific integrated circuit (ASIC), a field programmable gate array (FPGA), a digital signal processor (DSP), network processor, or the like. The processing device 591 is configured to execute instructions 592 for performing the operations and steps discussed herein. The computer system 590 can further include a network interface device 594 to communicate over the network 595.

The data storage system 598 can include a machine-readable storage medium 599 (also known as a computer-readable medium) on which is stored one or more sets of instructions 592 or software embodying any one or more of the methodologies or functions described herein. The instructions 592 can also reside, completely or at least partially, within the main memory 593 and/or within the processing device 591 during execution thereof by the computer system 590, the main memory 593 and the processing device 591 also constituting machine-readable storage media.

In one embodiment, the instructions 592 include instructions to implement functionality corresponding to the PU 102 of FIG. 1. While the machine-readable storage medium 599 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
prefetching data values corresponding to a first plurality of elements of a lookup table (LUT) from a first column of memory cells, wherein the first column is indicated by a first vector value of a plurality of vector values stored in a plurality of positions of a register;
shifting, by one position and toward a first position of the plurality of positions, each of the plurality of vector values stored in the register to cause a second position of the plurality of positions to be unoccupied; and
storing, in the second position of the register, one of the first plurality of elements indicated by the first vector value.

2. The method of claim 1, further comprising prefetching the first plurality of elements from the first column of memory cells as indicated by a first portion of a plurality of bits of the first vector value.

3. The method of claim 2, further comprising storing the one of the first plurality of elements indicated by a second portion of the plurality of bits of the first vector value.

4. The method of claim 1, further comprising, subsequent to storing the one of the first plurality of elements in the second position of the register:
prefetching a second plurality of elements of the lookup table from a second column of memory cells, wherein the second column is indicated by a second vector value of the plurality of vector values that is stored in the first position of the register;
shifting, by one position and toward the first position, each of the plurality of vector values stored in the register to cause the second position of the plurality of positions to be unoccupied; and
storing, in the second position of the register, one of the second plurality of elements indicated by the second vector value.

5. The method of claim 1, wherein:
the first plurality of elements respectively correspond to output values of the LUT; and
the method further comprises activating a row of memory cells configured to store data corresponding to the LUT prior to prefetching the data values corresponding to the first plurality of elements from the first column of memory cells.

6. An apparatus, comprising:
an array of memory cells; and
a processing unit comprising a register and coupled to the array, the processing unit configured to, to perform a table lookup operation:
sequentially prefetch a plurality of output values of a lookup table (LUT) from a respective column of memory cells of the array, wherein the respective column is indicated by a respective vector value of a plurality of vector values stored in a first position of the register;
subsequent to each prefetch of the respective column of memory cells, shift the plurality of vector values respectively stored a plurality of positions of the register by one position toward the first position to cause a second position of the register to be unoccupied; and
store, in the second position of the register, a respective output value of the plurality of output values indicated by the respective vector value of the plurality of vector values.

7. The apparatus of claim 6, wherein:
the processing unit further comprises a multiplexor to which the plurality of prefetched output values are received as respective inputs; and
the multiplexor is configured to:
select the respective output value of the plurality of prefetched output values to output to the register based on one or more bits of the respective vector value of the plurality of vector values.

8. The apparatus of claim 6, wherein:
the processing unit is a first processing unit and the array of memory cells is a first array of memory cells;
the apparatus further comprises a second array of memory cells and a second processing unit coupled to the second array;
wherein:
the first processing unit is configured to perform a first table lookup operation; and
the second processing unit is configured to perform a second table lookup operation concurrently with the first table lookup operation performed by the first processing unit.

9. The apparatus of claim 6, wherein the first position is an initial position of the plurality of positions of the register.

10. The apparatus of claim 6, wherein the second position is a terminal position of the plurality of positions of the register.

11. The apparatus of claim 6, wherein each vector value used to indicate the respective column and output value is discarded from the register as a result of each shift subsequent to the respective prefetching of the plurality of output values of the respective column of memory cells.

12. The apparatus of claim 6, wherein each vector value of the plurality of vector values comprises:
a number of first bits to indicate the respective column of memory cells of the array; and
a number of second bits to indicate the respective output value of the plurality of output values.

13. An apparatus, comprising:
an array of memory cells; and
a processing unit coupled to the array of memory cells and comprising:
a shift register; and
a multiplexor coupled to the shift register;
wherein the processing unit is configured to:
prefetch a first plurality of output values of a lookup table (LUT) from a first column of memory cells of the array, wherein the first column is indicated by a first portion of bits of a first vector value of a plurality of vector values respectively stored in a plurality of positions of the shift register;
shift, by one position and toward an initial position of the plurality of positions, each of vector value of the plurality of vector values stored in the shift register to cause a terminal position of the plurality of positions to be unoccupied; and
cause a second portion of bits of the first vector value to be input to the multiplexor, wherein the multiplexor is configured to select one of the first plurality of prefetched output values based on the second portion of bits of the first vector value.

14. The apparatus of claim 13, wherein a second vector value of the plurality of vector values is stored in the initial position as a result of the plurality of vector values being shifted toward to the initial position.

15. The apparatus of claim 13, wherein the processing unit is further configured to:
prefetch a second plurality of output values of the LUT from a second column of memory cells of the array, wherein the second column is indicated by a first portion of bits of a second vector value of the plurality of vector values;
shift, by one position and toward the initial position of the plurality of positions, each of data values respectively corresponding to the plurality of vector values stored in the shift register to cause the terminal position of the plurality of positions to be unoccupied; and
cause a second portion of bits of the second vector value to be input to the multiplexor, wherein the multiplexor is configured to select one of the second plurality of prefetched output values based on the second portion of bits of the second vector.

16. The apparatus of claim 15, wherein:
the one of the first plurality of prefetched output values indicated by the first vector value is a first output value; and
the first output value is shifted, by one position, to a first position of the plurality of positions from the terminal position.

17. The apparatus of claim 16, wherein:
the one of the second plurality of prefetched output values selected by the second vector value is a second output value and the second output value is stored in the terminal position of the shift register in response to being selected by the multiplexor; and
a third vector value of the plurality of vector values is stored in the initial position as a result of the plurality of vector values being shifted toward to the initial position.

18. The apparatus of claim 17, wherein the processing unit is further configured to:
prefetch a third plurality of output values of the LUT from a third column of memory cells of the array, wherein the third column is indicated by a first portion of bits of a third vector value of the plurality of vector values;
shift, by one position and toward the initial position of the plurality of positions, each of data values respectively corresponding to the plurality of vector values stored in the shift register to cause the terminal position of the plurality of positions to be unoccupied; and
cause a second portion of bits of the third vector value to be input to the multiplexor, wherein the multiplexor is configured to select one of the third plurality of prefetched output values based on the second portion of bits of the third vector value.

19. The apparatus of claim 18, wherein, subsequent to the prefetch of the third plurality of output values as indicated by the third vector value:
the first output value is shifted, by one position, to a second position of the plurality of positions from the first position; and
the second output value is shifted, by one position, to the first position of the plurality of positions from the terminal position.

20. The apparatus of claim 13, wherein the processing unit is configured to transfer one or more of a plurality of output values stored in the shift register external to the shift register.
